(19) United States
(12) Patent Application Publication
(10) Pub. No.: US 2024/0258422 A1
(43) Pub. Date: Aug. 1, 2024

(54) POWER MOSFET DEVICE WITH PROTECTION AGAINST THE CONTAMINANTS AND RELATED MANUFACTURING PROCESS

(71) Applicant: STMicroelectronics International N.V., Geneva (CH)

(72) Inventors: Cateno Marco CAMALLERI, Catania (IT); Alfio GUARNERA, Trecastagni (IT); Mario Giuseppe SAGGIO, Aci Bonaccorsi (IT)

(73) Assignee: STMicroelectronics International N.V., Geneva (CH)

(21) Appl. No.: 18/396,524

(22) Filed: Dec. 26, 2023

(30) Foreign Application Priority Data
Jan. 31, 2023 (IT) 102023000001455

(51) Int. Cl. H01L 29/78; H01L 29/08; H01L 29/10; H01L 29/423; H01L 29/66

(52) U.S. Cl. CPC H01L 29/7813; H01L 29/0865; H01L 29/1095; H01L 29/42364; H01L 29/66712

(57) ABSTRACT

The present disclosure is directed to a MOSFET device including a semiconductor body with: a plurality of source regions of a first conductivity type; a plurality of body regions of a second conductivity type, which form a plurality of channel regions; and a drain region of the first conductivity type. The MOSFET device further includes a plurality of insulated gate regions, each of which includes a respective gate conductive region and a respective gate dielectric region, which is partially interposed between the gate conductive region and corresponding source regions and is also partially interposed between the gate conductive region and corresponding channel regions. The MOSFET device further includes a plurality of barrier structures, each of which extends on a corresponding insulated gate region and includes at least one respective first barrier region of silicon nitride.

### BACKGROUND

### Technical Field

The present disclosure relates to a power metal oxide semiconductor field effect transistor (MOSFET) device with protection against contaminants and to the related manufacturing process thereof.

### Description of the Related Art

As is known, power MOSFET devices are MOSFET devices capable of withstanding very high currents (even of the order of hundreds of Amperes). Furthermore, it is known that inside a power MOSFET device the so-called gate region is insulated from the so-called channel region by means of a dielectric region; however, the Applicant has noticed how contaminants (in particular, metals and chemical species including hydrogen atoms) present outside the power MOSFET device may migrate through the dielectric region, up to reaching the channel region, causing an undesired variation of the electrical characteristics of the power MOSFET device, as well as a reduction in reliability.

### BRIEF SUMMARY

Various embodiments of the present disclosure provide a MOSFET device which overcomes, at least in part, the drawbacks of the prior art.

According to the present disclosure, a MOSFET device and a manufacturing method of a MOSFET device are provided. The MOSFET device includes, for example, a substrate including a drain region having a first conductivity type, first and second body regions having a second conductivity type and in the drain region, and first and second source regions having the first conductivity type. The first and second body regions are separated from each other by a portion of the drain region. The first and second source regions are in the first and second body regions, respectively. The MOSFET device also includes an insulated gate region directly overlying the portion of the drain region, and a first barrier region on the insulated gate region.

### BRIEF DESCRIPTION OF THE SEVERAL VIEWS OF THE DRAWINGS

For a better understanding of the present disclosure, embodiments thereof are now described, purely by way of non-limiting example, with reference to the attached drawings, wherein:

FIG. 1 schematically shows a cross-section of a portion of a MOSFET device;

FIG. 2 schematically shows a top view with portions removed of a part of the MOSFET device shown in FIG. 1;

FIG. 3 schematically shows a top view of a portion of a simplified version of the MOSFET device shown in FIG. 1;

FIG. 4 schematically shows a cross-section of a portion of a variant of the MOSFET device shown in FIG. 1;

FIG. 5 schematically shows a cross-section of a portion of a MOSFET device; and

FIGS. 6-10 schematically show cross-sections of a MOSFET device, during successive steps of a manufacturing process.

### DETAILED DESCRIPTION

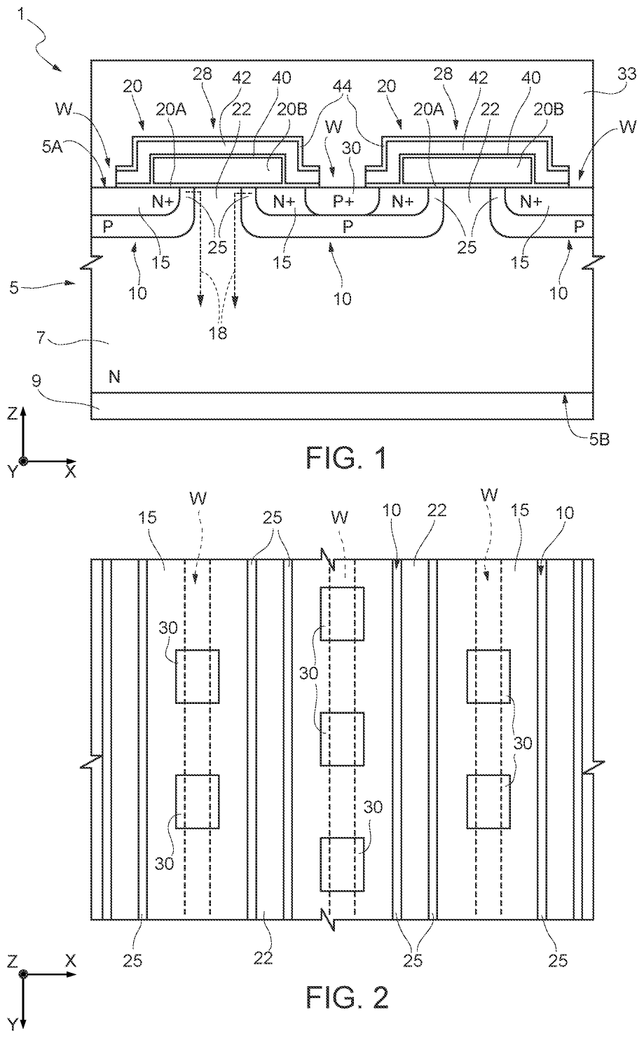

FIG. 1 shows a MOSFET device 1 for power applications and an orthogonal reference system XYZ.

The MOSFET device 1 is formed in a semiconductor body or substrate 5 of semiconductor material (for example, silicon, silicon carbide or gallium nitride), which is delimited at the top by a first surface 5A and is delimited at the bottom by a second surface 5B. The first and the second surfaces 5A, 5B are parallel to the plane XY.

The semiconductor body 5 comprises a drain region 7, a plurality of body regions 10 and a plurality of source regions 15.

The drain region 7, here of the N type, extends between the first and the second surfaces 5A, 5B of the body 5.

A drain contact region 9, of conductive material (for example, a metal or a silicide), extends on the second surface 5B of the semiconductor body 5, in direct electrical contact with the drain region 7, and forms a drain terminal of the MOSFET device 1.

The body regions 10 are of the P type and extend into the semiconductor body 5, starting from the first surface 5A. For example, each body region 10 has a doping level comprised between 1·10¹⁶ atoms/cm³ and 1·10¹⁹ atoms/cm³. Furthermore, the body regions 10 are laterally spaced parallel to the axis X; consequently, a corresponding surface portion 22 of the drain region 7, which faces the first surface 5A, extends between each pair of adjacent body regions 10. Furthermore, the body regions 10 have an elongated shape parallel to the axis Y.

The source regions 15 are of the N+ type, with a doping level comprised for example between 1·10¹⁸ atoms/cm³ and 5·10²⁰ atoms/cm³. Each source region 15 extends inside a respective body region 10, starting from the first surface 5A. Parallel to the axis X, each source region 15 has a smaller width with respect to the width of the corresponding body region 10; furthermore, along the axis Z, the source region 15 has a shallower depth with respect to the depth of the corresponding body region 10, in a manner such that the source region 15 is surrounded both laterally and at the bottom by the body region 10.

In greater detail, the source regions 15 have an elongated shape parallel to the axis Y, as visible in FIG. 2. Furthermore, each source region 15 and each surface portion 22 of the drain region 7 adjacent to the source region 12 laterally delimit a corresponding portion of the body region 10 having the source region 15 extending therein, referred to as the channel region 25. In practice, each channel region 25 faces the first surface 5A and extends between a corresponding surface portion 22 of the drain region 7 and the respective source region 15.

The MOSFET device 1 also comprises a plurality of insulated gate regions 20, which have elongated shapes parallel to the axis Y and are arranged staggered parallel to the axis X. Each insulated gate region 20 comprises: a respective gate dielectric layer 20A, which is made for example of oxide (for example, deposited oxide) and extends on the first surface 5A of the semiconductor body 5; a respective gate conductive region 20B, which is made of conductive material (for example, polysilicon) and is arranged on the gate dielectric layer 20A, in direct contact; and a barrier structure 28, which overlies the gate conductive region 20B, as described in greater detail below.

In greater detail, for each insulated gate region 20, the respective gate dielectric layer 20A extends on a corresponding surface portion 22 of the drain region 7 and over the two channel regions 25 adjacent to said respective surface portion 22, in direct contact; furthermore, the gate dielectric layer 20A extends on parts of the two source regions 15 adjacent to the aforementioned two channel regions 25. The gate conductive region 20B overlies portions of the gate dielectric layer 20A which overlie the respective surface portion 22, the channel regions 25 adjacent to the latter and first portions of the two source regions 15 adjacent to these channel regions 25. The gate conductive region 20B leaves exposed (i.e., is laterally staggered with respect to) portions of the gate dielectric layer 20A which overlie second portions of the two source regions 15 adjacent to these channel regions 25.

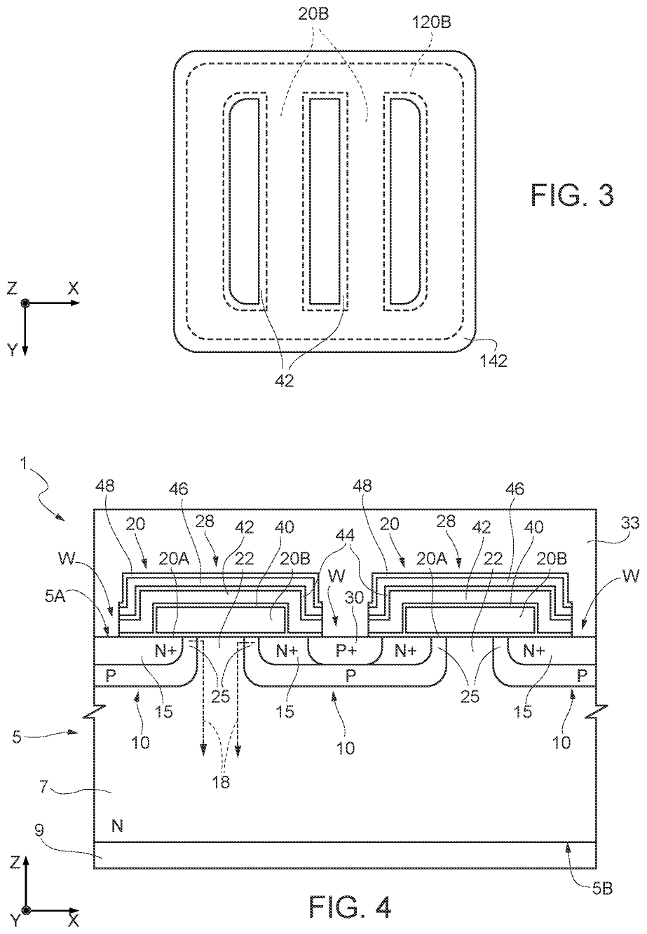

The gate conductive regions 20B of the insulated gate regions 20 are set in electrical contact, so as to form a gate terminal of the MOSFET device 1, which, in a manner not shown, is electrically accessible from the outside world, to allow the gate conductive regions 20B to be biased. For example, as shown in FIG. 3, which represents a simplified version of the MOSFET device 1 with two gate conductive regions 20B, the MOSFET device 1 may comprise an annular conductive region 120B, which surrounds the gate conductive regions 20B and is in direct contact with the ends of the gate conductive regions 20B, forming a monolithic conductive region therewith, of a same conductive material.

The MOSFET device 1 further comprises a plurality of body contact regions 30.

The body contact regions 30 are of P+ type. Furthermore, each body contact region 30 extends inside a corresponding source region 15, starting from the first surface 5A; in particular, each body contact region 30 extends through the corresponding source region 15, up to contacting the underlying corresponding body region 10.

Without any loss of generality, in the example shown in FIGS. 1 and 2, each source region 15 accommodates a plurality of respective body contact regions 30, which are arranged, staggered, along a corresponding direction parallel to the axis Y, so as to be separate from each other. In other words, a respective group of body contact regions 30 corresponds to each source region 15.

Again without any loss of generality, as visible in FIG. 2, the body contact regions 30 of adjacent source regions 15 are arranged staggered, in such a way that, parallel to the axis X, no overlapping of the body contact regions 30 of adjacent source regions 15 occurs. Furthermore, and again purely by way of example, groups of body contact regions 30 of a first and a second type alternate parallel to the axis X, which differ in that the body contact regions 30 have a staggered arrangement parallel to the axis Y.

As visible in FIG. 1 with reference to one body contact region 30, for each insulated gate region 20, the portions of the gate dielectric layer 20A which are laterally staggered with respect to the gate conductive region 20B also extend on parts of the body contact regions 30 which extend into the two source regions 15 adjacent to the respective surface portion 22 of the drain region 7, leaving in any case exposed, as previously mentioned, parts of each of these source regions 15 and part of each of these body contact regions 30. The body contact regions 30 are instead laterally staggered with respect to the gate conductive regions 20B.

The gate dielectric layers 20A may form a single monolithic dielectric region; for example, in a per se known manner and therefore not shown, the MOSFET device 1 may comprise an annular dielectric region, which surrounds the gate dielectric layers 20A and is in direct contact with the ends of the gate dielectric layers 20A, forming indeed a single dielectric region therewith.

As previously mentioned, the MOSFET device 1 also comprises, for each insulated gate region 20, a respective barrier structure 28.

Each barrier structure 28 is a multilayer region, which includes a number of dielectric regions superimposed on each other. In particular, as visible in FIG. 1, each barrier structure 28 comprises a respective first insulating region 40, a respective barrier region 42 and a respective second insulating region 44, which have elongated shapes parallel to the axis Y.

In detail, the first insulating region 40 is made for example of oxide (for example, a deposited or thermally grown oxide) and covers the corresponding gate conductive region 20B, in direct contact. In particular, the first insulating region 40 overlies the corresponding gate conductive region 20B and furthermore also laterally surrounds the corresponding gate conductive region 20B, up to contacting, at the bottom, the corresponding gate dielectric layer 20A, with which it seals the gate conductive region 20B. For example, the first insulating region 40 may be formed by the same dielectric material that forms the gate dielectric layer 20A, so as to form a single monolithic dielectric region with the latter. For example, the first insulating region 40 has a thickness comprised between 5 nm and 1000 nm.

The barrier region 42 is formed of silicon nitride (SiN) and has a thickness for example greater than or equal to 30 nm (for example, at least equal to 70 nm). Furthermore, the barrier region 42 extends on the first insulating region 40, in direct contact; in addition, the barrier region 42 extends, in direct contact, on the portions of the corresponding gate dielectric layer 20A that are laterally offset with respect to the gate conductive region 20B. In this manner, the barrier region 42 overlies and laterally surrounds, at a distance, the gate conductive region 20B.

The second insulating region 44 is made for example of oxide (for example, deposited oxide) and extends on the barrier region 42, in direct contact. For example, the second insulating region 44 has a thickness comprised between 5 nm and 1000 nm.

Again with reference to the barrier structures 28, they laterally delimit windows W, which have an elongated shape parallel to the axis Y and face the aforementioned exposed parts of corresponding body contact regions 30 and the exposed parts of the source regions 15. Purely by way of example, in FIG. 2 the profile of the windows W is shown in dashed lines.

Furthermore, without any loss of generality, the first insulating regions 40 may be formed by parts of a first monolithic insulating region.

The barrier regions 42 may be formed by corresponding parts of a single silicon nitride monolithic region. In other words, as visible in FIG. 3, the MOSFET device 1 may comprise an annular barrier region 142, which surrounds the barrier regions 42 and is in direct contact with the ends of the barrier regions 42, forming indeed the aforementioned silicon nitride monolithic region therewith.

Again without any loss of generality, the second insulating regions 44 may be formed by parts of a second monolithic insulating region. Although not shown, in top view the first and the second monolithic insulating regions may have approximately the same shape as the silicon nitride monolithic region.

The MOSFET device 1 further comprises a front metallization region 33, which is formed for example by metal and/or metal silicide and extends over the first surface 5A of the semiconductor body 5. In particular, the front metallization region 33 extends above the barrier structures 28 and, through the windows W, contacts the exposed parts of the source regions 15 and the body contact regions 30.

In practice, the front metallization region 33 forms a source terminal of the MOSFET device 1. Furthermore, thanks to the front metallization region 33, the body contact regions 30 are set at the same potential as the source regions 15, in such a way as to reset the gain of the source-body-drain parasitic NPN transistor.

In use, each insulated gate region 20 forms, together with the adjacent source regions 15, an elementary cell of the MOSFET device 1, which has a respective threshold voltage Vₜₕ. If the voltage V_{GS} between the gate terminal and the source terminal is greater than the threshold voltage Vₜₕ, the MOSFET device 1 is in an on-state, wherein the channel regions 25 are conductive (since a so-called N-type channel is formed therein) and a current may flow between the source terminal and the drain terminal, along a plurality of conductive paths 18 (two shown in FIG. 1 with dashed arrows). Each conductive path 18 has a horizontal portion, which traverses a corresponding channel region 25, and a vertical portion, which traverses the surface portion 22 of the drain region 7 having the channel region 25 facing thereon, in the direction of the drain contact region 9. The intensity of the current depends on the value of the voltage V_{DS} between the source terminal and the drain terminal of the MOSFET device 1.

If the voltage V_{GS} is lower than the threshold voltage Vₜₕ, the MOSFET device 1 is in an off-state, since the channel regions 25 are not conductive. Furthermore, the voltage V_{DS} between the source terminal and the drain terminal is applied to the PN junctions formed by the body regions 10 and the drain region 7.

This having been said, the Applicant has observed how the presence of the barrier region 42 allows to reduce the probability that metals and chemical species including hydrogen atoms present outside the MOSFET device 1 may migrate through the barrier structure 28, up to reaching the channel regions 25 arranged below the barrier structure 28. In this manner, the degradation of the performances of the MOSFET device 1 is prevented.

In order to further reduce the probability that contaminants present outside the MOSFET device 1 may reach the channel regions 25, it is possible that, as shown in FIG. 4, each barrier structure 28 includes a second barrier region 46 of silicon nitride and, optionally, a third insulating region 48. In particular, the second barrier region 46 extends on the second insulating region 44, in direct contact, and has a thickness for example greater than or equal to 30 nm; the second insulating region 48 is formed for example by deposited oxide and extends on the second barrier region 46, in direct contact.

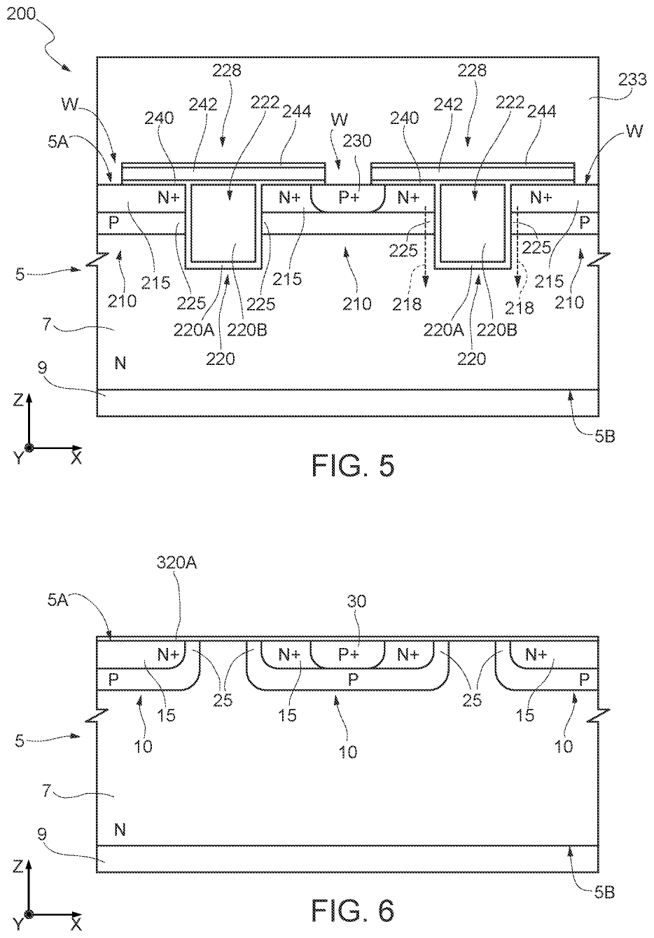

FIG. 5 shows a different embodiment. In particular, FIG. 5 shows a MOSFET device 200 for power applications, which will be described hereinafter limitedly to the differences with respect to the MOSFET device 1; elements already present in the MOSFET device 1 are indicated with the same reference signs, unless otherwise specified.

In detail, the MOSFET device 200 is a vertical conduction device. Furthermore, parallel to the axis X, each source region (here indicated by 215) has the same width with respect to the width of the corresponding body region (here indicated by 210); consequently, each source region 215 overlies a corresponding body region 210. As regards the body contact regions (here indicated by 230), what has been described with reference to the MOSFET device 1 applies.

A corresponding trench 222 extends between each pair of adjacent source regions 215, which has a depth such that it also extends between the underlying pair of body regions 210.

Approximately, each trench 222 has a parallelepiped-shaped section and axis parallel to the axis Y. Top portions of the side walls of each trench 222 are delimited by portions of the corresponding pair of adjacent source regions 215; intermediate portions of the side walls of each trench 222 are delimited by portions of the corresponding pair of body regions 210, hereinafter referred to as the channel regions 225; furthermore, the bottom and bottom portions of the side walls of the trench 222 are delimited by the drain region 7.

Inside each trench 222 extends a corresponding gate dielectric layer (here indicated by 220A), which is formed for example by oxide and coats the bottom and the side walls of the trench 222, without filling the trench 222. In fact, a corresponding gate conductive region 220B, formed by conductive material (for example, polysilicon), also extends inside the trench 222. The gate conductive region 220B is surrounded laterally and at the bottom by the gate dielectric layer 220A, in direct contact; furthermore, the top part of the gate conductive region 220B faces the first surface 5A.

In practice, each gate dielectric layer 220A and each gate conductive region 220B form a corresponding insulated gate region (here indicated by 220), which extends into a corresponding trench 222. Furthermore, each trench 222 is closed at the top by a corresponding barrier structure (here indicated by 228).

In detail, each barrier structure 228 comprises a respective first insulating region 240, a respective barrier region 242 and a respective second insulating region 244, which have elongated shapes parallel to the axis Y.

In greater detail, the first insulating region 240 is formed for example by oxide (for example, deposited oxide), has a thickness comprised for example between 30 nm and 1000 nm and extends above the first surface 5A. In particular, the first insulating region 240 extends, in direct contact, above the gate conductive region 220B and above portions of the gate dielectric layer 220A which face the first surface 5A; in particular, the first insulating region 240 may be formed by the same material as the gate dielectric layer 220A, with which it forms a region which seals the gate conductive region 220B. Furthermore, the first insulating region 240 extends, in direct contact, on portions of the source regions 215 adjacent to the trench 222, and thus overlies, at a distance, the corresponding channel regions 225. Furthermore, the first insulating region 240 extends, in direct contact, on portions of the body contact regions 230 which extend into these source regions 215. As was already the case for MOSFET device 1, in any case the first insulating regions 240 leave exposed parts of the source regions 215 and of the body contact regions 230.

The barrier region 242 is made of silicon nitride (SiN) and has a thickness for example greater than or equal to 30 nm. Furthermore, the barrier region 242 extends on the first insulating region 240, in direct contact, so as to entirely cover the first insulating region 240. Consequently, the barrier region 242 extends at a distance above the gate dielectric layer 220A and the gate conductive region 220B, as well as, again at a distance, above portions of the source regions 215 adjacent to the trench 222 and the underlying channel regions 225. Furthermore, without any loss of generality, the barrier region 242 extends at a distance above portions of the body contact regions 230.

The second insulating region 244 is made for example of oxide (for example, deposited oxide) and extends on the barrier region 242, in direct contact. For example, the second insulating region 244 has a thickness comprised between 30 nm and 1000 nm.

As already described with reference to the MOSFET device 1, although not shown, the gate conductive regions 220B are set in electrical contact in a per se known manner, to form the gate terminal of the MOSFET device 200, which is electrically accessible from the outside world, to allow the gate conductive regions 220B to be biased.

Furthermore, although not shown, and without any loss of generality, the first insulating regions 240 may be formed by corresponding parts of a first monolithic insulating region; the barrier regions 242 may be formed by corresponding parts of a single monolithic silicon nitride region; the second insulating regions 244 may be formed by corresponding parts of a second monolithic insulating region.

Again with reference to the barrier structures 228, they laterally delimit the windows W, which face the exposed parts of corresponding body contact regions 230 and the exposed parts of corresponding source regions 215.

The front metallization region (here indicated by 233) extends above the barrier structures 228 and contacts the exposed parts of the source regions 215 and the body contact regions 230. The front metallization region 233 forms the source terminal of the MOSFET device 200.

The operation of the MOSFET device 200 is similar to that of the MOSFET device 1. In particular, if the voltage V_{GS} between the gate terminal and the source terminal is greater than the threshold voltage Vₜₕ, the MOSFET device 200 is in an on-state, wherein the channel regions 225 are conductive (since a so-called N-type channel is formed) and a current may flow between the source terminal and the drain terminal, along a plurality of conductive paths 218 (two shown in FIG. 5 with dashed arrows), which are vertical. If the voltage V_{GS} is lower than the threshold voltage Vₜₕ, the MOSFET device 200 is in an off-state, since the channel regions 225 are not conductive.

The barrier structures 228 allow, thanks to the presence of the barrier regions 242, to reduce the probability that metals and chemical species including hydrogen atoms present outside the MOSFET device 200 may migrate up to reaching the channel regions 225, ensuring the same advantages described with reference to the MOSFET device 1. Furthermore, as already described with reference to the MOSFET device 1 and therefore not further shown, in order to further reduce the probability that contaminants may reach the channel regions 225, each barrier structure 228 may include a second silicon nitride barrier region and, optionally, a third insulating region. However, the presence of the insulating regions allows the mechanical stresses to be reduced. Furthermore, the multilayer structure, with suitably sized thicknesses, possibly allows the barrier structures to act as dielectric mirrors during any laser annealing operations, protecting the underlying gate conductive regions and the underlying channel regions.

Steps of a manufacturing process of the MOSFET device 1 are described hereinbelow.

In detail, as shown in FIG. 6, the semiconductor body 5 is formed in a per se known manner; furthermore, a dielectric layer 320A is formed on the first surface 5A of the semiconductor body 5. For example, the dielectric layer 320A is formed by oxide, either thermally grown or deposited.

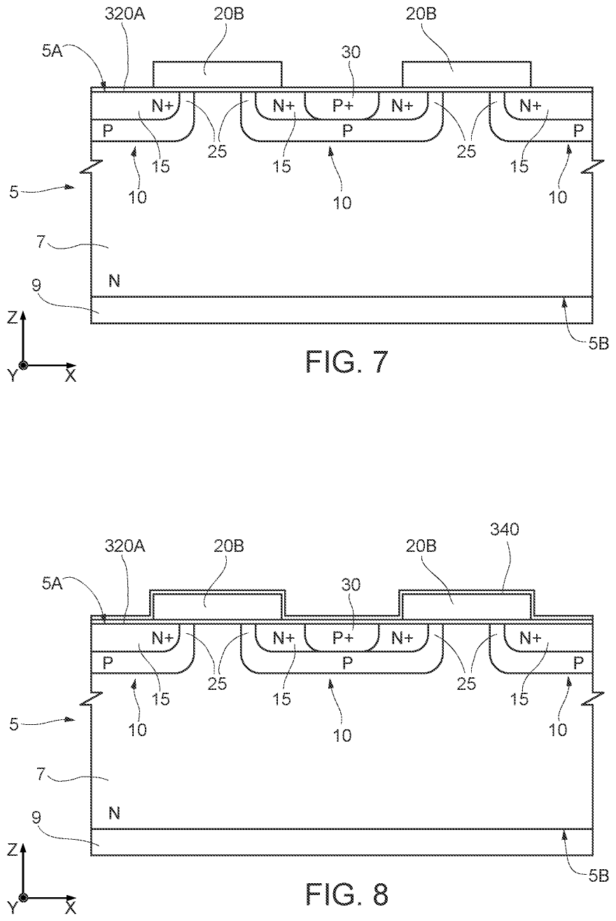

Then, as shown in FIG. 7, the gate conductive regions 20B are formed by, for example, forming a conductive layer on the dielectric layer 320A.

Subsequently, as shown in FIG. 8, a first oxide layer 340 is formed, for example by deposition, so that the first oxide layer 340 covers the gate conductive regions 20B at the top and laterally and also extends on the exposed portions of the dielectric layer 320A.

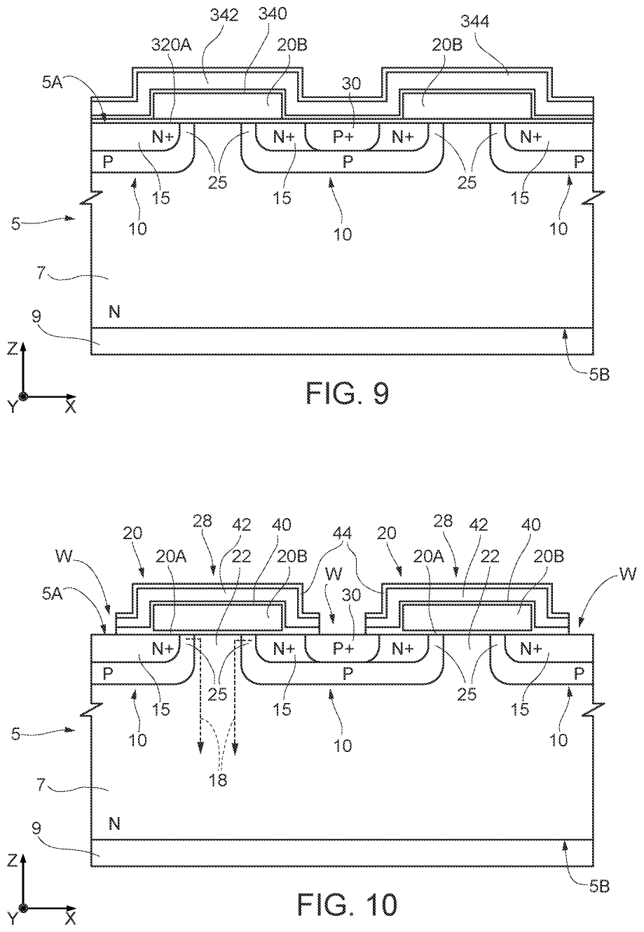

Subsequently, as shown in FIG. 9, a barrier layer 342 of silicon nitride is formed on the first oxide layer 340, for example by low pressure chemical vapor deposition (LPCVD); then, a second oxide layer 344 is formed on the barrier layer 342, for example by deposition. The barrier layer 342 has, for example, a thickness greater than or equal to 30 nm.

Then, as shown in FIG. 10, portions of the second oxide layer 344 and underlying portions of the barrier layer 342, of the first oxide layer 340 and of the dielectric layer 320A are selectively removed, so as to form the windows W. The remaining portions of the second oxide layer 344 and of the barrier layer 342 form the second insulating regions 44 and the barrier regions 42, respectively. The remaining portions of the first oxide layer 340 form the first insulating regions 40 and form, together with portions of the dielectric layer 320A laterally staggered with respect to the gate conductive regions 20B, the portions of the gate dielectric layers 20A laterally staggered with respect to the gate conductive regions 20B; the portions of the dielectric layer 320A below the gate conductive regions 20B form the portions of the gate dielectric layers 20A arranged below the gate conductive regions 20B. In this regard, in FIG. 10 it is visible that the portions of the gate dielectric layers 20A laterally staggered with respect to the gate conductive regions 20B may have a greater thickness with respect to the portions of the gate dielectric layers 20A arranged below the gate conductive regions 20B; for ease of view, this detail has not been shown in FIGS. 1 and 4.

Then, the manufacturing process may proceed in a per se known manner.

Although not shown, the previously described manufacturing process may be applied, with modifications, also to manufacture the MOSFET device 200. In particular, forming the passivation structures 228 may follow the same process flow described with reference to the MOSFET device 1.

Finally, it is clear that modifications and variations may be made to the MOSFET devices and to the manufacturing process previously described and illustrated, without departing from the scope of the present disclosure.

For example, each barrier structure may also include more than two barrier regions. The first insulating region may be absent, in which case each barrier region contacts the underlying gate conductive region; the second insulating region may also be absent.

The conductivity types of the drain region, the source regions, the body regions and the body contact regions may be inverted with respect to what has been described.

Regarding the manufacturing process, the insulating regions and the barrier regions may be formed in a different manner with respect to what has been described.

A MOSFET device (1; 200) comprising a semiconductor body (5) may include: a plurality of source regions (15; 215) of a first conductivity type; a plurality of body regions (10; 210) of a second conductivity type, which form a plurality of channel regions (25; 225); and a drain region (7) of the first conductivity type; said MOSFET device (1; 200) may further include a plurality of insulated gate regions (20; 220), each of which comprises a respective gate conductive region (20B; 220B) and a respective gate dielectric region (20A; 220A), which is partially interposed between the gate conductive region (20B; 220B) and corresponding source regions (15; 215) and is also partially interposed between the gate conductive region (20B; 220B) and corresponding channel regions (25; 225); said MOSFET device (1; 200) further comprising a plurality of barrier structures (28; 228), each of which extends on a corresponding insulated gate region (20; 220) and comprises at least one respective first barrier region (42; 242) of silicon nitride.

Each first barrier region (42; 242) may have a thickness greater than or equal to 30 nm.

Each first barrier region (42; 242) may overlie, at a distance, the corresponding channel regions (25; 225).

Each barrier structure (28; 228) may include a respective bottom insulating region (40; 240), which extends on the corresponding gate conductive region (20B; 220B), in direct contact; and each first barrier region (42; 242) may extend on the corresponding bottom insulating region (40; 240).

Each barrier structure (28; 228) may further include a respective top insulating region (44; 244), which extends on the corresponding first barrier region (42; 242), in direct contact.

Each barrier structure (28) may further include at least one respective second barrier region (46) of silicon nitride, which extends on the corresponding top insulating region (40; 240).

The gate conductive regions (20B; 220B) may be of polysilicon.

The semiconductor body (5) may further include, for each source region (15; 215), a corresponding plurality of body contact regions (30; 230) of the second conductivity type, each of which extends inside the source region (15; 215), starting from the front surface (5A), up to contacting an underlying corresponding body region (10; 210).

The MOSFET device may further include a source metallization (33; 233), which partially overlies the barrier structures (28; 228) and in part extends through the barrier structures (28; 228), in contact with the source regions (15; 215) and the body contact regions (30; 230).

The semiconductor body (5) may be delimited by a first surface (5A), and the body regions (10) may extend inside the drain region (7), starting from the first surface (5A), and may be laterally staggered, in such a way that pairs of adjacent body regions (10) are separated by a corresponding surface portion (22) of the drain region (7), which faces the first surface (5A); and each source region (15) may extend inside a corresponding body region (10), the channel regions (25) being formed by portions of the body regions (10) which may be arranged laterally with respect to the source regions (15) and face the first surface (5A); and each gate dielectric region (20A; 220A) may extend on the first surface (5A) and may overlie a corresponding surface portion (22) of the drain region (7), corresponding channel regions (25) and portions of corresponding source regions (15); and each gate conductive region (20B) may extend on the corresponding gate dielectric region (20A).

The semiconductor body (5) may be delimited by a first surface (5A), and the source regions (215) may face the first surface (5A) and may overlie corresponding body regions (210); and each insulated gate region (20; 220) may extend inside a corresponding trench (222), which may extend inside the semiconductor body (5), starting from the first surface (5A), and may be interposed between a corresponding pair of source regions (215) and a corresponding pair of body regions (210); and each gate conductive region (220B) and the corresponding gate dielectric region (220A) may extend inside the corresponding trench (222), the gate dielectric region (220A) surrounding the gate conductive region (220B) and contacting the corresponding pair of source regions (215) and the corresponding pair of body regions (210); and the channel regions (225) may be formed by portions of the body regions (210) which contact the gate dielectric regions (220A).

A process for manufacturing a MOSFET device (1; 200) may include forming a semiconductor body (5), said step of forming a semiconductor body (5) including: forming a plurality of source regions (15; 215) of a first conductivity type; forming a plurality of body regions (10; 210) of a second conductivity type, which form a plurality of channel regions (25; 225); and forming a drain region (7) of the first conductivity type; said process may further include: forming a plurality of insulated gate regions (20; 220), each of which comprises a respective gate conductive region (20B; 220B) and a respective gate dielectric region (20A; 220A), which is partially interposed between the gate conductive region (20B; 220B) and corresponding source regions (15; 215) and is also partially interposed between the gate conductive region (20B; 220B) and corresponding channel regions (25; 225); forming a plurality of barrier structures (28; 228), each of which extends on a corresponding insulated gate region (20; 220) and comprises at least one respective barrier region (42; 242) of silicon nitride.

Forming a plurality of barrier structures (28; 228) may include forming, by deposition, a silicon nitride layer (342) above the insulated gate regions (20; 220), and subsequently selectively removing portions of the silicon nitride layer (342).

The manufacturing process may further include forming an oxide layer (340) on the gate conductive regions (20B), in direct contact; and forming a silicon nitride layer (342) may include forming the silicon nitride layer (342) on the oxide layer (340).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A metal oxide semiconductor field effect transistor (MOSFET) device comprising:
a semiconductor body;
a plurality of source regions of a first conductivity type in the semiconductor body;
a plurality of body regions of a second conductivity type in the semiconductor body, the plurality of body regions including a plurality of channel regions;
a drain region of the first conductivity type in the semiconductor body;
a plurality of insulated gate regions, each of the plurality of insulated gate regions including:
a gate conductive region; and
a gate dielectric region partially interposed between the gate conductive region and a corresponding source region and partially interposed between the gate conductive region and a corresponding channel region; and
a plurality of barrier structures, each of the plurality of barrier structures extending on a corresponding insulated gate region and including a first barrier region of silicon nitride.

2. The MOSFET device according to claim 1, wherein the first barrier region has a thickness greater than or equal to 30 nanometers.

3. The MOSFET device according to claim 1, wherein the first barrier region overlies, at a distance, the corresponding channel region.

4. The MOSFET device according to claim 1, wherein
each of the plurality of barrier structures includes an insulating region on and in direct contact with a corresponding gate conductive region, and
each first barrier region is on a corresponding insulating region.

5. The MOSFET device according to claim 1, wherein each of the plurality of barrier structures includes an insulating region on and in direct contact with a corresponding first barrier region.

6. The MOSFET device according to claim 5, wherein each of the plurality of barrier structures includes a second barrier region of silicon nitride on a corresponding insulating region.

7. The MOSFET device according to claim 1, wherein the gate conductive regions include poly silicon.

8. The MOSFET device according to claim 1, further comprising:
a plurality of body contact regions of the second conductivity type in the plurality of source regions, each of the plurality of body contact regions extending inside a corresponding source region, starting from a front surface of the semiconductor body, up to contacting an underlying corresponding body region.

9. The MOSFET device according to claim 8, further comprising:
a source metallization, which partially overlies the plurality of barrier structures and in part extends through the plurality of barrier structures, in contact with the plurality of source regions and the plurality of body contact regions.

10. The MOSFET device according to claim 1,
wherein the semiconductor body is delimited by a first surface; and
wherein the plurality of body regions extend inside the drain region, starting from the first surface, and are laterally staggered, in such a way that pairs of adjacent body regions are separated by a corresponding surface portion of the drain region, which faces the first surface;
wherein each of the plurality of source regions extends inside a corresponding body region, the plurality of channel regions being formed by portions of the plurality of body regions that are arranged laterally with respect to the plurality of source regions and face the first surface;
wherein the gate dielectric region extends on the first surface and overlies a corresponding surface portion of the drain region, corresponding channel regions and portions of corresponding source regions; and
wherein the gate conductive region extends on the gate dielectric region.

11. The MOSFET device according to claim 1,
wherein the semiconductor body is delimited by a first surface;
wherein the plurality of source regions face the first surface and overlie corresponding body regions;
wherein each of the plurality of insulated gate regions extends inside a corresponding trench, which extends inside the semiconductor body, starting from the first surface, and is interposed between a corresponding pair of source regions and a corresponding pair of body regions;
wherein the gate conductive region and the gate dielectric region extend inside the corresponding trench, the gate dielectric region surrounding the gate conductive region and contacting the corresponding pair of source regions and the corresponding pair of body regions; and
wherein the plurality of channel regions are formed by portions of the body regions that contact gate dielectric regions.

12. A process for manufacturing a metal oxide semiconductor field effect transistor (MOSFET) device comprising:
forming a plurality of source regions of a first conductivity type in a semiconductor body;
forming a plurality of body regions of a second conductivity type in the semiconductor body, the plurality of body regions including a plurality of channel regions;
forming a drain region of the first conductivity type in the semiconductor body; forming a plurality of insulated gate regions, each of the plurality of insulated gate regions including:
a gate conductive region; and
a gate dielectric region partially interposed between the gate conductive region and a corresponding source regions and partially interposed between the gate conductive region and a corresponding channel region; and
forming a plurality of barrier structures, each of the plurality of barrier structures extending on a corresponding insulated gate region and including a barrier region of silicon nitride.

13. The process according to claim 12, wherein forming the plurality of barrier structures includes forming a silicon nitride layer on the plurality of insulated gate regions, and subsequently selectively removing portions of the silicon nitride layer.

14. The process according to claim 13, further comprising:
forming an oxide layer on the gate conductive regions, in direct contact,
wherein forming the silicon nitride layer includes forming the silicon nitride layer on the oxide layer.

15. A device, comprising:
a substrate including:
a drain region having a first conductivity type;
first and second body regions having a second conductivity type and in the drain region, the first and second body regions separated from each other by a portion of the drain region; and
first and second source regions having the first conductivity type, the first and second source regions in the first and second body regions, respectively;
an insulated gate region directly overlying the portion of the drain region; and
a first barrier region on the insulated gate region.

16. The device of claim 15, wherein the insulated gate region includes:
a first insulating layer on the substrate;
a conductive layer on the first insulating layer; and
a second insulating layer on the conductive layer.

17. The device of claim 16, further comprising:
a second barrier region on the first barrier region, the second barrier region including:
a second conductive layer on the second insulating layer; and
a third insulating layer on the second conductive layer.

18. The device of claim 15, wherein the first barrier region includes silicon nitride.

19. The device of claim 15 wherein the first source region includes a body contact region having the second conductivity type.

20. The device of claim 15, further comprising:
a metallization layer on the first barrier region.
